(19) United States
(12) Patent Application Publication
(10) Pub. No.: US 2015/0170921 A1
(43) Pub. Date: Jun. 18, 2015

(54) METHOD FOR MANUFACTURING SEMICONDUCTOR DEVICE

(71) Applicant: Mitsubishi Electric Corporation, Tokyo (JP)

(72) Inventor: Yoshihiko Hanamaki, Tokyo (JP)

(21) Appl. No.: 14/464,786

(22) Filed: Aug. 21, 2014

(30) Foreign Application Priority Data
Dec. 17, 2013 (JP) 2013-260582

(51) Int. Cl. H01L 21/285; H01L 21/324

(52) U.S. Cl. CPC H01L 21/28575; H01L 21/3245

(57) ABSTRACT

A method of making an ohmic contact from a multi-metal-layer includes increasing a temperature in an annealing furnace containing the multi-metal-layer to a temperature within a first temperature range, from a temperature lower by 100° C. than a minimum melting point, which is the lowest melting point among melting points of the respective layers of the multi-metal-layer, to the minimum melting point, maintaining the temperature within the first temperature range, increasing the temperature in the furnace to a temperature to within a second temperature range, lower than a maximum melting point, which is the highest melting point of the respective layers of the multi-metal-layer, to higher than the minimum melting point among melting points of the respective layers of the multi-metal-layer, at a temperature increasing speed of 5° C./sec to 20° C./sec, and maintaining the temperature within the second temperature range.

### BACKGROUND OF THE INVENTION

1. Field of the Invention

The present invention relates to a method for manufacturing a semiconductor device including an ohmic electrode provided to supply power to, for example, a semiconductor element.

2. Background Art

Journal of Applied Physics Vol. 89 p 3143-p 3150 discloses a technique for forming an ohmic electrode provided to supply power to a semiconductor element through heat treatment instead of ion injection.

On a wafer, many ohmic electrodes are formed so as to contact a semiconductor element formed on the wafer. The resistance value of a contact between the semiconductor element and the ohmic electrodes is preferably uniform within the surface of the wafer. However, the method for forming an ohmic electrode through heat treatment disclosed in Journal of Applied Physics Vol. 89 p 3143-p 3150 has a problem that uniformity of the contact resistance value within the surface of the wafer is insufficient.

### SUMMARY OF THE INVENTION

The present invention has been implemented to solve the above-described problem and it is an object of the present invention to provide a method for manufacturing a semiconductor device capable of improving uniformity of the contact resistance value within the surface of the wafer.

The features and advantages of the present invention may be summarized as follows.

According to one aspect of the present invention, a method for manufacturing a semiconductor device, includes a step of forming a multi-metal-layer for each of a plurality of semiconductor elements formed on a wafer, a step of placing the wafer into an annealing furnace, a first temperature increasing step of increasing a temperature in the annealing furnace to a temperature within a first temperature range from a temperature lower by 100° C. than a minimum melting point which is a lowest melting point among melting points of the respective layers of the multi-metal-layer to the minimum melting point, a temperature maintaining step of maintaining the temperature within the first temperature range for 30 sec to 150 sec after the first temperature increasing step, a second temperature increasing step of increasing the temperature in the furnace to a temperature within a second temperature range lower than a maximum melting point which is a highest melting point and higher than the minimum melting point among melting points of the respective layers of the multi-metal-layer, after the temperature maintaining step at a temperature increasing speed of 5° C./sec to 20° C./sec, and an annealing step of maintaining the temperature within the second temperature range for 30 sec to 150 sec after the second temperature increasing step and forming an ohmic electrode of the multi-metal-layer, wherein the multi-metal-layer has no eutectic point at a temperature lower than the maximum melting point.

Other and further objects, features and advantages of the invention will appear more fully from the following description.

### BRIEF DESCRIPTION OF THE DRAWINGS

FIG. 1 is a cross-sectional view of a semiconductor device;

FIG. 2 shows heat treatment procedure;

FIG. 3 is a graph illustrating results of measuring contact resistance values at seven points within the surface of the wafer of the present invention;

FIG. 4 is a graph illustrating results of measuring contact resistance values at seven points within the surface of the wafer manufactured without the temperature maintaining step;

FIG. 5 is a cross-sectional view of a semiconductor device according to the second embodiment; and

FIG. 6 shows heat treatment procedure.

### DETAILED DESCRIPTION OF THE PREFERRED EMBODIMENTS

A method for manufacturing a semiconductor device according to embodiments of the present invention will be described with reference to the accompanying drawings. The same or corresponding components will be assigned the same reference numerals and duplicate description may be omitted.

### First Embodiment

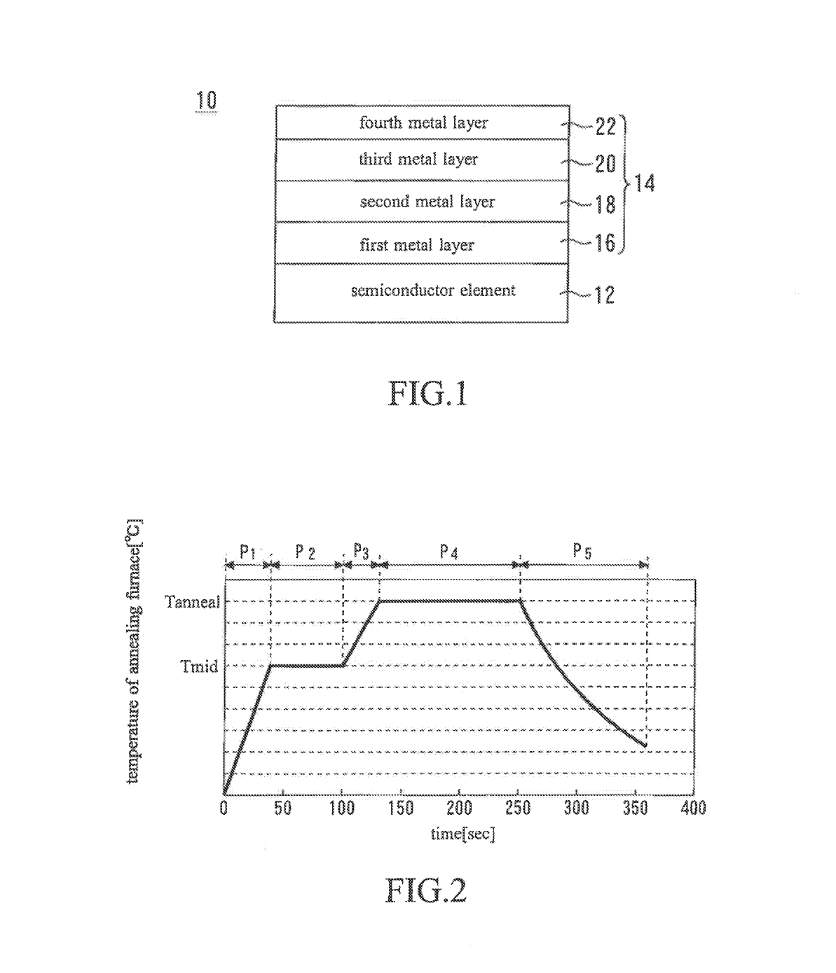

FIG. 1 is a cross-sectional view of a semiconductor device 10. The semiconductor device 10 is provided with a semiconductor element 12. A multi-metal-layer 14 is formed on the semiconductor element 12. The multi-metal-layer 14 is formed on a specific portion of the semiconductor element 12, for example, to supply power to the semiconductor element 12. The multi-metal-layer 14 is provided with a first metal layer 16, a second metal layer 18, a third metal layer 20 and a fourth metal layer 22. The multi-metal-layer 14 as a whole constitutes one ohmic electrode.

A method for manufacturing a semiconductor device according to the first embodiment of the present invention will be described. In the method for manufacturing a semiconductor device according to the first embodiment of the present invention, the multi-metal-layer 14 is formed for each of a plurality of semiconductor elements formed on a wafer. That is, a plurality of multi-metal-layers 14 are formed on the wafer. The multi-metal-layer 14 is formed using, for example, a vacuum deposition method or sputtering method.

A melting point of the first metal layer 16 is t1, a melting point of the second metal layer 18 is t2which is lower than t1, a melting point of the third metal layer 20 is t3which is lower than t2, and a melting point of the fourth metal layer 22 is t4 which is lower than t3. The lowest melting point among the melting points of the respective layers of the multi-metal-layer 14 is called a “minimum melting point.” The minimum melting point is t4. The highest melting point among the melting points of the respective layers of the multi-metal-layer 14 is called a “maximum melting point.” The maximum melting point is t1. Note that the multi-metal-layer 14 has no eutectic point at a temperature lower than the maximum melting point.

Next, the wafer is placed in an annealing furnace. Next, the multi-metal-layer 14 is subjected to heat treatment in the annealing furnace. The heat treatment will be described with reference to FIG. 2. First, an initial period P1 will be described. The temperature of the multi-metal-layer 14 at a start point of the period P1 is normally a room temperature. The temperature in the annealing furnace is increased to a temperature within a first temperature range from a temperature by 100° C. lower than the minimum melting point (t4) to the minimum melting point. This step is called a “first temperature increasing step.”

The temperature increasing speed in the first temperature increasing step is not particularly limited, and ranges, for example, 5° C./sec to 50° C./sec. The method of increasing the temperature in the furnace is not particularly limited, and is, for example, resistance heating or lamp irradiation.

Next, a period P2 will be described. In the period P2, after the first temperature increasing step, the temperature within the first temperature range is maintained for 30 sec to 150 sec. This step is called a “temperature maintaining step.” In the temperature maintaining step, the temperature may be temporally changed within the first temperature range or a specific temperature within the first temperature range may be maintained.

Next, a period P3 will be described. In the period P3, after the temperature maintaining step, the temperature in the furnace is increased to a temperature within a second temperature range which is lower than the maximum melting point and higher than the minimum melting point. This step is called a “second temperature increasing step.” The temperature increasing speed in the second temperature increasing step is assumed to be 5° C./sec to 20° C./sec.

Next, a period P4 will be described. In the period P4, after the second temperature increasing step, a temperature within the second temperature range is maintained for 30 sec to 150 sec and ohmic electrodes are formed using the multi-metal-layer 14. This step is called an “annealing step.” The annealing step causes alloying reaction to take place between the semiconductor element 12 and the multi-metal-layer 14, which lowers an electronic barrier or positive hole barrier between the semiconductor element and the multi-metal-layer.

Next, a period P5 will be described. In the period P5, the annealing furnace is cooled and returned to the room temperature. This step is called a “cooling step.” The cooling method is not particularly limited, and, for example, natural cooling may be adopted. The method for manufacturing a semiconductor device according to the first embodiment of the present invention forms a plurality of multi-metal-layers 14 on a wafer according to the above-described steps.

In the temperature maintaining step, mutual diffusion (solid layer diffusion) takes place between the first metal layer 16, second metal layer 18, third metal layer 20 and fourth metal layer 22, and differences in melting points between these layers are reduced. A time of 30 sec to 150 sec is necessary to allow mutual diffusion to take place sufficiently. Providing the temperature maintaining step allows temperature uniformity within the surface of the wafer to improve compared to a case without the temperature maintaining step.

In the second temperature increasing step, by limiting the temperature increasing speed from 5° C./sec to 20° C./sec, it is possible to increase the temperature within the second temperature range while maintaining satisfactory temperature uniformity within the surface of the wafer. When the temperature increasing speed is less than 5° C./sec, impurity (residual oxygen or water content or the like) is taken into the electrode material. On the other hand, when the temperature increasing speed is greater than 20° C./sec, temperature uniformity within the surface of the wafer during the temperature rise deteriorates. Therefore, in the second temperature increasing step, the temperature increasing speed is limited to 5° C./sec to 20° C./sec. This makes it possible to execute the annealing step while maintaining temperature uniformity within the surface of the wafer and thereby improve uniformity of the contact resistance value within the surface of the wafer between the semiconductor element 12 and the ohmic electrode (multi-metal-layer 14).

Since the multi-metal-layer 14 has no eutectic point at a temperature lower than the maximum melting point, it is possible to prevent the whole multi-metal-layer 14 from melting in the annealing step.

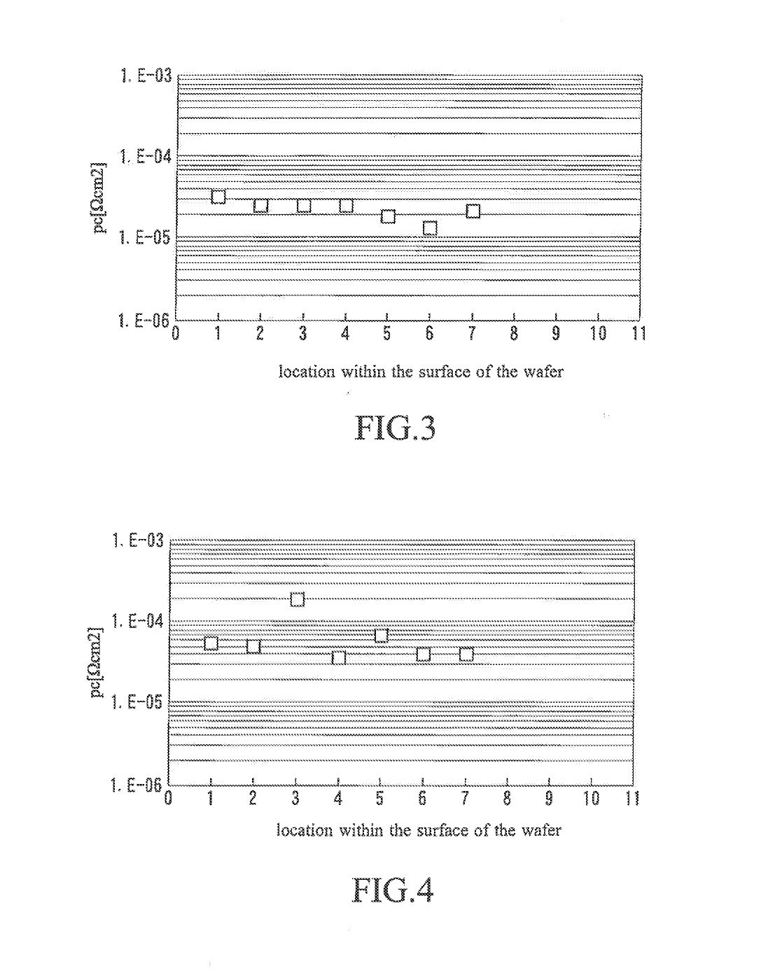

FIG. 3 is a graph illustrating results of measuring contact resistance values at seven points within the surface of the wafer of the semiconductor device manufactured using the method for manufacturing a semiconductor device according to the first embodiment of the present invention. Contact resistance values with substantially no variation are obtained in the respective points within the surface of the wafer. FIG. 4 is a graph illustrating results of measuring contact resistance values at seven points within the surface of the wafer of the semiconductor device manufactured using the manufacturing method with the temperature maintaining step excluded from the method for manufacturing a semiconductor device according to the first embodiment of the present invention. Variations of contact resistance values are observed at the respective points within the surface of the wafer.

The order of arrangement of the respective layers making up the multi-metal-layer 14 is not particularly limited. The number of layers making up the multi-metal-layer 14 is not particularly limited. The semiconductor element 12 is generally made of Si. However, when the semiconductor element 12 is made to function as a high-frequency element, the semiconductor element 12 may be formed of nitride compound semiconductor such as GaN. Note that the above-described modification is applicable to the method for manufacturing a semiconductor device according to the following embodiment.

### Second Embodiment

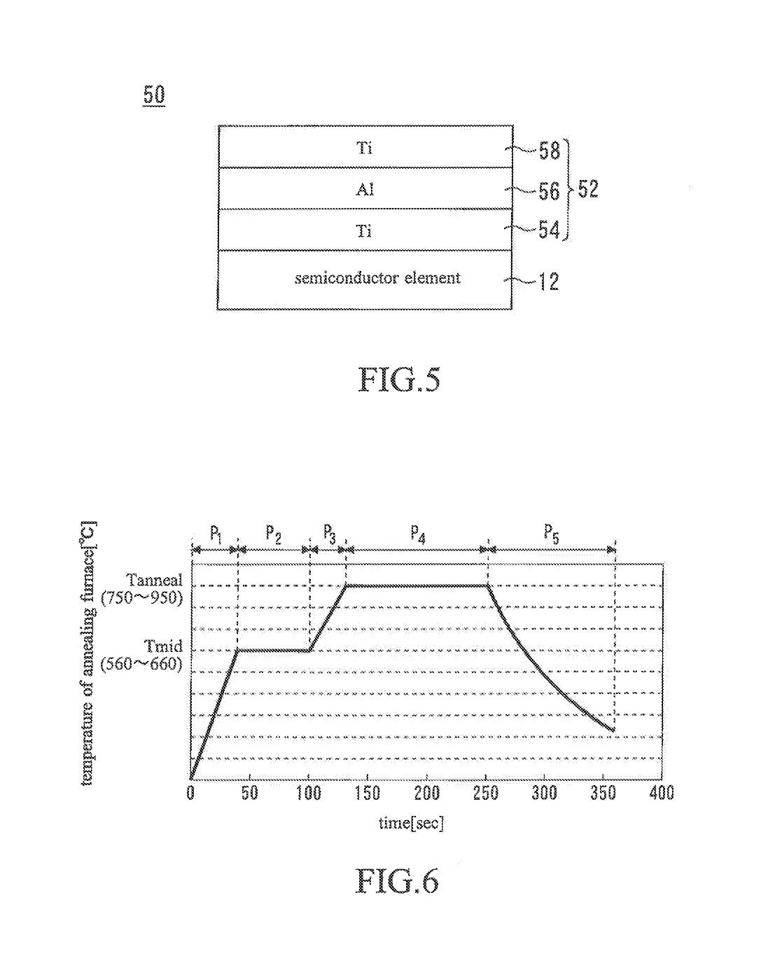

A method for manufacturing a semiconductor device according to a second embodiment of the present invention relates to the method for manufacturing a semiconductor device according to the first embodiment in which Ti and Al are adopted as the multi-metal-layer. FIG. 5 is a cross-sectional view of a semiconductor device 50 according to the second embodiment of the present invention. A multi-metal-layer 52 is provided with a Ti layer 54 formed on the semiconductor element 12 as a first metal layer, an Al layer 56 formed on the Ti layer 54 as a second metal layer and a Ti layer 58 formed on the Al layer 56 as a third metal layer.

The Ti layer 54 which is the first metal layer and the Ti layer 58 which is the third metal layer are made of the same material. Melting points of the Ti layers 54 and 58 are 1668° C. and a melting point of the Al layer 56 is 660° C. The Ti layers 54 and 58, and the Al layer 56 have no eutectic point. The method for manufacturing the semiconductor device 50 will be described hereinafter.

First, the multi-metal-layer 52 is formed for each of a plurality of semiconductor elements formed on a wafer. Next, the wafer is placed into an annealing furnace. Next, the wafer is subjected to heat treatment. The heat treatment will be described with reference to FIG. 6. A first temperature increasing step (period P1) will be described. A minimum melting point which is the lowest melting point among melting points of the respective layers of the multi-metal-layer 52 is 660° C. A first temperature range is a range from a temperature (560° C.) lower by 100° C. than the minimum melting point to the minimum melting point (660° C.). In the first temperature increasing step, the temperature in the furnace is increased to a temperature within the first temperature range (560° C. to 660° C.).

Next, in the temperature maintaining step (period P2), the temperature within the first temperature range (560° C. to 660° C.) is maintained for 30 sec to 150 sec. Next, in the second temperature increasing step (period P3), the temperature in the furnace is increased to a temperature within the second temperature range lower than the maximum melting point (1668° C.) which is the highest melting point and higher than the minimum melting point (660° C.) among the melting points of the respective layers of the multi-metal-layer 52. The temperature increasing speed in the second temperature increasing step ranges from 5° C./sec to 20° C./sec. In the second embodiment of the present invention, the temperature in the furnace is increased to 750° C. to 950° C. which is a temperature within the second temperature range.

Next, in the annealing step (period P4), 750° C. to 950° C. which is a temperature within the second temperature range is maintained for 30 sec to 150 sec and ohmic electrodes are formed of the multi-metal-layer 52. Finally, in the cooling step (period P5), the temperature in the furnace is cooled to on the order of the room temperature.

The difference in melting point between Ti and Al is very large, exceeding 1000° C. For this reason, when the multi-metal-layer 52 is made of Ti and Al, a temperature difference is likely to occur between the central area and the perimeter of the wafer. For example, when the multi-metal-layer containing Ti and Al is heated from the room temperature to a temperature in the annealing step (e.g., 900° C.) at a stretch and annealing is performed, a slip line may occur, or the composition of the compound semiconductor may become non-uniform or warpage of the wafer may occur. All of these events may cause uniformity of the contact resistance value within the surface of the wafer to degrade.

According to the method for manufacturing a semiconductor device according to the second embodiment of the present invention, in the temperature maintaining step of maintaining a temperature of 560° C. to 660° C., mutual diffusion is assumed to have occurred in which Al of the Al layer 56 is diffused into the Ti layers 54 and 58 and Ti of the Ti layers 54 and 58 is diffused into the AI layer 56. This mutual diffusion causes the melting points of the Ti layers 54 and 58 to be lower than 1668° C. and causes the melting point of the Al layer 56 to be higher than 660° C. That is, the difference in melting points decreases. Therefore, temperature variations within the surface of the wafer can be reduced.

Regarding the time in the temperature maintaining step, if this time is shorter than 30 sec or longer than 150 sec, uniformity of the contact resistance value within the surface of the wafer is not improved and rather degraded, and so this time is set to 30 sec to 150 sec. Providing 30 sec or more for the temperature maintaining step, it is assumed that Ti and Al are mutually diffused sufficiently. A mechanism when the temperature maintaining step is set to be longer than 150 sec is unknown.

In the second temperature increasing step, the temperature increasing speed is set to 5° C./sec to 20° C./sec, and therefore the temperature can be increased while maintaining the temperature uniformity within the surface of the wafer. Therefore, it is possible to cause alloying reaction between the semiconductor element and the multi-metal-layer to advance in the annealing step while maintaining the temperature uniformity within the surface of the wafer.

In the second temperature increasing step, if the temperature increasing speed is set to less than 5° C./sec, a problem may occur in which impurity (residual oxygen or water content or the like) in the annealing furnace may be taken into the electrode material during the temperature rise. On the other hand, when the temperature increasing speed is set to be greater than 20° C./sec, temperature uniformity within the surface of the wafer during the temperature rise cannot be maintained.

In the annealing step, the processing time is preferably set to 30 sec to 150 sec. Within a processing time shorter than 30 sec, alloying reaction between the semiconductor element and the multi-metal-layer does not advance sufficiently. Alternatively, within a processing time longer than 150 sec, the temperature within the surface of the wafer is estimated to be non-uniform, but details are yet to be ascertained.

An important point of the present invention is execute the temperature maintaining step before the annealing step. In the temperature maintaining step, components of the respective layers of the multi-metal-layer are made to diffuse, then differences in melting points therebetween are reduced and temperature uniformity within the surface of the wafer is improved. To sufficiently reduce the difference in melting points, the time in the temperature maintaining step is set to 30 sec or more and 150 sec or less. The second temperature increasing step is executed so as not to lose the temperature uniformity within the surface of the wafer thus obtained and the annealing step is executed. Various modifications are possible as long as this feature is not lost.

In the second embodiment, the Ti layer and the Al layer are adopted as the layers making up the multi-metal-layer, but the present invention is not limited to this. If there are differences in melting points between the respective layers making up the multi-metal-layer, it is possible to improve temperature uniformity within the surface of the wafer and improve uniformity of contact resistance values within the surface of the wafer using the method for manufacturing a semiconductor device of the present invention.

The present invention promotes diffusion of each layer of the multi-metal-layer, improves temperature uniformity within the surface of the wafer and then anneals the multi-metal-layer, and can thereby improve uniformity of the contact resistance value within the surface of the wafer.

Obviously many modifications and variations of the present invention are possible in the light of the above teachings. It is therefore to be understood that within the scope of the appended claims the invention may be practiced otherwise than as specifically described.

1. A method for manufacturing a semiconductor device, comprising:
forming a multi-metal-layer for each of a plurality of semiconductor elements, wherein the semiconductor elements are on a wafer;
placing the wafer into an annealing furnace;
increasing temperature in the annealing furnace a first time to a temperature within a first temperature range that ranges from a temperature lower by 100° C. than a minimum melting point which is the lowest melting point among melting points of the respective layers of the multi-metal-layer, to the minimum melting point;
maintaining the temperature within the first temperature range for 30 sec to 150 sec after increasing the temperature the first time;
increasing the temperature in the furnace a second time to a temperature within a second temperature range that ranges from lower than a maximum melting point which is the highest melting point, of the respective layers of the multi-metal-layer, to higher than the minimum melting point among melting points of the respective layers of the multi-metal-layer, after maintaining the temperature within the first temperature range, at a temperature increasing speed in a range from 5° C./sec to 20° C./sec; and
maintaining the temperature within the second temperature range for 30 sec to 150 sec after increasing the temperature the second time, forming an ohmic electrode of the multi-metal-layer, wherein the multi-metal-layer has no eutectic point at a temperature lower than the maximum melting point.

2. The method for manufacturing a semiconductor device according to claim 1, wherein the multi-metal-layer comprises
a first metal layer on the semiconductor element,
a second metal layer on the first metal layer, and
a third metal layer, the same material as the first metal layer, on the second metal layer.

3. The method for manufacturing a semiconductor device according to claim 2, wherein
the first metal layer and the third metal layer are Ti, and
the second metal layer is Al.

4. The method for manufacturing a semiconductor device according to claim 1, wherein the semiconductor element includes a nitride compound semiconductor material.
